(19) United States
(12) Patent Application Publication
(10) Pub. No.: US 2026/0123411 A1
(43) Pub. Date: Apr. 30, 2026

(54) SEMICONDUCTOR PACKAGE

(71) Applicant: Samsung Electronics Co., Ltd., Suwon-si (KR)

(72) Inventors: Gyosoo Choo, Suwon-si (KR); Kwangyong Lee, Suwon-si (KR); Kwanghoe Heo, Suwon-si (KR); Moosung Kim, Suwon-si (KR); Yeonwook Jung, Suwon-si (KR)

(21) Appl. No.: 19/305,245

(22) Filed: Aug. 20, 2025

(30) Foreign Application Priority Data
Oct. 30, 2024 (KR) 10-2024-0151023

(51) Int. Cl. H01L 23/00; H01L 23/367; H01L 25/065; H01L 25/18; H10B 80/00; H10D 80/30

(52) U.S. Cl. CPC H10W 40/22; H10W 90/00; H10B 80/00; H10D 80/30; H10W 72/073; H10W 72/07332; H10W 72/07352; H10W 72/07353; H10W 72/07354; H10W 72/321; H10W 72/325; H10W 72/331; H10W 72/334; H10W 72/347; H10W 72/348; H10W 72/353; H10W 72/354; H10W 72/5445; H10W 72/865; H10W 72/884; H10W 90/20; H10W 90/24; H10W 90/288; H10W 90/732; H10W 90/734; H10W 90/752; H10W 90/754; H10W 90/755

(57) ABSTRACT

A semiconductor package includes a substrate including a wiring; a chip stack including a plurality of semiconductor chips stacked on the substrate, wherein each of the plurality of semiconductor chips has upper and lower surfaces, opposite to each other, front and rear surfaces, opposite to each other, left and right surfaces, opposite to each other, and connection pads disposed on the upper surface adjacent to the front surface; bonding wires electrically connecting the connection pads to the wiring of the substrate; a plurality of attachment films disposed on the lower surface of each of the plurality of semiconductor chips; a mold layer covering the chip stack and the bonding wires; and connection bumps disposed below the substrate, and electrically connected to the wiring, wherein at least one of the plurality of attachment films covers the rear surface of at least one semiconductor chip among the plurality of semiconductor chips.

### CROSS-REFERENCE TO RELATED APPLICATION(S)

This application claims the benefit Korean Patent Application No. 10-2024-0151023 filed in the Korean Intellectual Property Office on Oct. 30, 2024, the entire disclosure of which is incorporated herein by reference.

### BACKGROUND

As an electronic device becomes lighter and has higher performance, development of a highly integrated semiconductor chip is desired. An increase in the amount of heat generated by a small and highly-integrated semiconductor chip may cause degradation in the performance of the semiconductor chip. Accordingly, a semiconductor package technology is desired to effectively release heat generated by the semiconductor chip.

### SUMMARY

In general, the present disclosure is directed toward a semiconductor package having improved heat dissipation characteristics and reliability.

According to some implementations, the present disclosure is direct to a semiconductor package that includes a substrate including a wiring; a chip stack including a plurality of semiconductor chips stacked on the substrate, wherein each of the plurality of semiconductor chips has upper and lower surfaces, opposite to each other, front and rear surfaces, opposite to each other, left and right surfaces, opposite to each other, and connection pads disposed on the upper surface adjacent to the front surface; bonding wires electrically connecting the connection pads to the wiring of the substrate; a plurality of attachment films disposed on the lower surface of each of the plurality of semiconductor chips; a mold layer covering the chip stack and the bonding wires; and connection bumps disposed below the substrate, and electrically connected to the wiring, wherein at least one of the plurality of attachment films covers the rear surface of at least one semiconductor chip among the plurality of semiconductor chips.

According to some implementations, the present disclosure is directed to a semiconductor package comprising a substrate; at least one chip stack including a plurality of semiconductor chips stacked on the substrate, wherein each of the plurality of semiconductor chips includes a front surface and a rear surface, opposite to each other in a first direction, and a left surface and a right surface, opposite to each other in a second direction, intersecting the first direction; bonding wires electrically connecting the plurality of semiconductor chips to the substrate; and a plurality of attachment films respectively disposed below a corresponding semiconductor chip among the plurality of semiconductor chips, wherein at least one of the plurality of attachment films has a first length in the first direction and a second length in the second direction, the semiconductor chip corresponding to the at least one attachment film has a first width in the first direction and a second width in the second direction, and at least one of the first length and the second length is greater than at least one of the first width and the second width.

According to some implementations, the present disclosure is directed to a semiconductor package comprising a substrate; a first chip stack disposed on the substrate, and including a first upper semiconductor chip and a first intermediate semiconductor chip between the substrate and the first upper semiconductor chip; bonding wires electrically connecting the first upper semiconductor chip and the first intermediate semiconductor chip to the substrate; a first upper attachment film disposed below the first upper semiconductor chip; and a first intermediate attachment film disposed below the first intermediate semiconductor chip, wherein a length of the first upper attachment film in a first direction is greater than a width of the first upper semiconductor chip in the first direction.

### BRIEF DESCRIPTION OF DRAWINGS

Example implementations will be more clearly understood from the following detailed description, taken in conjunction with the accompanying drawings.

FIG. 1A is a perspective view of an example of a semiconductor package according to some implementations, and FIG. 1B is a cross-sectional view taken along line I-I′ of FIG. 1A according to some implementations.

FIG. 2 is a perspective view of an example of a semiconductor package according to some implementations.

FIG. 3 is a perspective view of an example of a semiconductor package according to some implementations.

FIG. 4 is a perspective view of an example of a semiconductor package according to some implementations.

FIG. 5A is a perspective view of an example of a semiconductor package according to some implementations, and FIG. 5B is a plan view of an intermediate semiconductor chip illustrated in 5A according to some implementations.

FIG. 6 is a perspective view of an example of a semiconductor package according to some implementations.

FIG. 7 is a cross-sectional side view of an example of a semiconductor package according to some implementations.

FIGS. 8A to 8C are drawings for illustrating an example of a manufacturing process of an attachment film including a bent portion according to some implementations.

FIGS. 9A to 9C are drawings for illustrating an example of a manufacturing process of a semiconductor package of FIG. 1A according to some implementations.

FIGS. 10A to 10C are drawings for illustrating an example of a manufacturing process of a semiconductor package of FIG. 5A according to some implementations.

### DETAILED DESCRIPTION

Hereinafter, example implementation will be explained in detail with reference to the accompanying drawings.

Hereinafter, with reference to the accompanying drawings, example embodiments of the present inventive concept will be described as follows. Unless otherwise specified, in this specification, terms such as ‘upper,’ ‘upper surface,’ ‘lower,’ ‘lower surface,’ ‘side’ and the like are based on the drawings, and actually, may vary depending on the direction in which the components are disposed.

In addition, ordinal numbers such as “first,” “second,” “third,” or the like may be used as labels for specific elements, step portions, directions, or the like to distinguish various elements, step portions, directions, or the like from each other. Terms that are not described using “first,” “second,” or the like in the specification may still be referred to as “first” or “second” in the claims. Additionally, terms referenced by a specific ordinal number (for example, “first” in a particular claim) may be described elsewhere with a different ordinal number (for example, “second” in the specification or another claim).

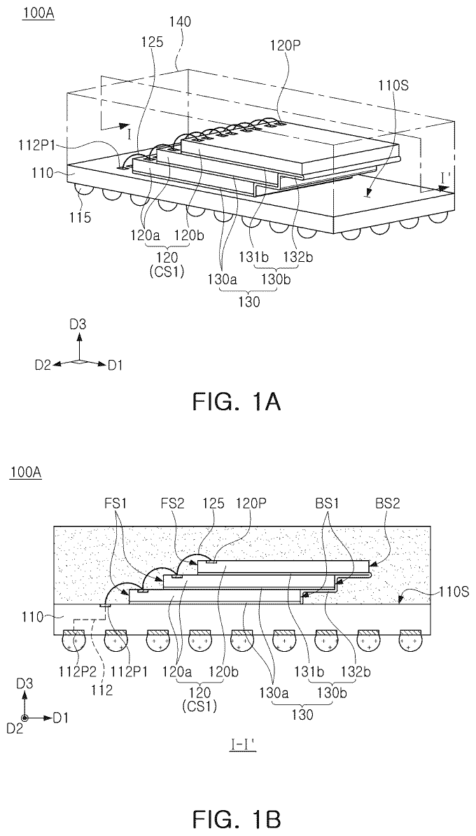

FIG. 1A is a perspective view of an example of a semiconductor package according to some implementations, and FIG. 1B is a cross-sectional view taken along line I-I′ of FIG. 1A according to some implementations. In FIGS. 1A and 1B, a semiconductor package 100A may include a substrate 110, a plurality of semiconductor chips 120, and a plurality of attachment films 130. According to some implementations, the semiconductor package 100A may further include a mold layer 140. According to some implementations, at least a portion of the plurality of attachment films 130 may be in contact with each other to effectively dissipate heat generated by the semiconductor chip 120. For example, at least one of the plurality of attachment films 130 (e.g., ‘130b’) may form a heat dissipation path connected to one side (e.g., ‘BS1’) of at least one of the plurality of semiconductor chips 120 (e.g., ‘120a’) and/or an upper surface 1105 of the substrate 110, thereby improving the heat dissipation characteristics of the semiconductor package 100A.

The substrate 110 may be a semiconductor package substrate including a printed circuit board (PCB), a ceramic substrate, a glass substrate, a tape wiring board, or the like. For example, the substrate 110 may be a double-sided printed circuit board (double-sided PCB) or a multilayer printed circuit board (multilayer PCB).

The substrate 110 may include bonding pads 112P1, bump pads 112P2, and a wiring 112 electrically connecting the same. The bonding pads 112P1 may be disposed on an upper surface of the substrate 110, and the bump pads 112P2 may be disposed on a lower surface of the substrate 110. The bonding pads 112P1 and the bump pads 112P2 may include at least one metal or an alloy of two or more metals selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

Connection bumps 115 may be disposed below the bump pads 112P2. The connection bumps 115 may be electrically connected to the semiconductor chip 120 through the wiring 112. The connection bumps 115 may include, for example, tin (Sn) or an alloy containing tin (Sn) (e.g., Sn—Ag—Cu). The connection bumps 115 may be electrically connected to an external device such as a module substrate, a system board, or the like.

The plurality of semiconductor chips 120 may include non-volatile memory chips, such as a flash memory, a phase-change random access memory (PRAM), a magnetoresistive random access memory (MRAM), a ferroelectric random access memory (FeRAM), or a resistive random access memory (RRAM), and/or volatile memory chips, such as a dynamic random access memory (DRAM) or a static random access memory (SRAM). The plurality of semiconductor chips 120 may include the same type of memory chip, but the present disclosure is not limited thereto. In some implementations, the plurality of semiconductor chips 120 may include different types of memory chips.

A plurality of semiconductor chips 120 may be disposed on a substrate 110 so that lower surfaces thereof face the substrate 110. The plurality of semiconductor chips 120 may include connection pads 120P disposed on upper surfaces thereof. The connection pads 120P may include one of copper (Cu), nickel (Ni), titanium (Ti), aluminum (Al), or an alloy thereof. The plurality of semiconductor chips 120 may be electrically connected to bonding pads 112P1 of the substrate 110 through bonding wires 125. The bonding wires 125 may connect the connection pads 120P of the plurality of semiconductor chips (120) to the bonding pads 112P1 of the substrate 110. The bonding wires 125 may include gold (Au), silver (Ag), lead (Pb), aluminum (Al), copper (Cu), or an alloy thereof, but the present disclosure is not limited thereto. The plurality of semiconductor chips 120 may be attached to or mutually attached to the substrate 110 by the attachment films 130.

The plurality of semiconductor chips 120 may be stacked on the substrate 110, and may form at least one chip stack CS1. Here, the chip stack CS1 may be understood as a set of semiconductor chips 120 forming a single channel or a plurality of channels. Each of the plurality of semiconductor chips 120 may include upper and lower surfaces, opposite to each other, front surfaces FS1 and FS2 and rear surfaces BS1 and BS2, opposite to each other, and left and right surfaces, opposite to each other. Here, the upper and lower surfaces of the semiconductor chip 120 may be disposed opposite to each other in a vertical direction D3, the front surfaces FS1 and FS2 and the rear surfaces BS1 and BS2 of the semiconductor chip 120 may be disposed opposite to each other in a first direction D1, and the left surface and the right surface of the semiconductor chip 120 may be disposed opposite to each other in a second direction D2. Connection pads 120P may be disposed on an upper surface adjacent to the front surfaces FS1 and FS2. The plurality of semiconductor chips 120 may be offset in a direction toward the rear surfaces BS1 and BS2 so that the connection pads 120P are exposed in the vertical direction D3. The plurality of semiconductor chips 120 may include an upper semiconductor chip 120b and at least one intermediate semiconductor chip 120a disposed between the substrate 110 and the upper semiconductor chip 120b.

A plurality of attachment films 130 may be flexible films formed using a synthetic resin. The plurality of attachment films 130 may be formed of a synthetic resin, such as, for example, an epoxy resin, a phenolic resin, a melamine resin, a polyester resin, a silicone resin, a urethane resin, a polyamide resin, or an acrylic resin. The plurality of attachment films 130 may be a die attach film (DAF), but the present disclosure is not limited thereto. The plurality of attachment films 130 may include at least one of thermally conductive fillers, for example, alumina (Al₂O₃), aluminum nitride (AlN), boron nitride (BN), magnesium oxide (MgO), zinc oxide (ZnO), and silica (SiO₂).

A plurality of attachment films 130 may be respectively disposed below a corresponding semiconductor chip among a plurality of semiconductor chips 120. The plurality of attachment films 130 may be in contact with a lower surface of the corresponding semiconductor chip 120. The plurality of attachment films 130 may include an upper attachment film 130b disposed on a lower surface of the upper semiconductor chip 120b, and an intermediate attachment film 130a disposed on a lower surface of the intermediate semiconductor chip 120a.

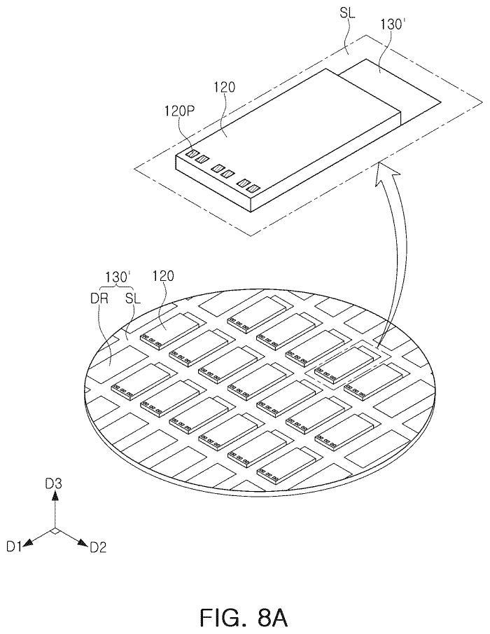

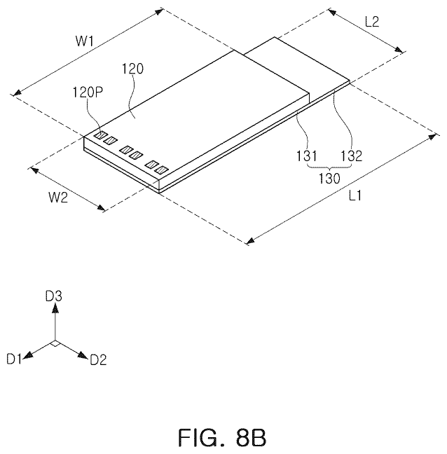

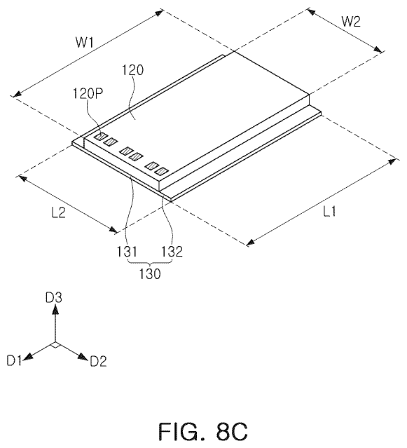

In some implementations, at least one attachment film 130 among the plurality of attachment films 130 may have a length greater than a width of the corresponding semiconductor chip 120 in a horizontal direction (D1 and/or D2 direction). At least one of the first length in the first direction D1 and the second length in the second direction D2 of the at least one attachment film 130 may be greater than at least one of the first width in the first direction D1 and the second width in the second direction D2 of the corresponding semiconductor chip 120 (see. FIGS. 8B and 8C).

In some implementations, the first length of the upper attachment film 130b in the first direction D1 may be greater than the first width of the upper semiconductor chip 120b in the first direction D1, and the second length of the upper attachment film 130b in the second direction D2 may be equal to the second width of the upper semiconductor chip 120b in the second direction D2. At least one attachment film 130 among the plurality of attachment films 130 may cover the rear surfaces BS1 and BS2 of at least one semiconductor chip 120.

The upper attachment film 130b may contact at least one of the rear surfaces BS1 of the intermediate semiconductor chip 120a facing the first direction D1 (see FIGS. 1A, 2, 5A, 6, and 7), or may contact the rear surface BS2 of the upper semiconductor chip 120b (see FIG. 3). The upper attachment film 130b may include an attachment portion 131b contacting the lower surface of the upper semiconductor chip 120b, and a bent portion 132b contacting the rear surface BS1 of the intermediate semiconductor chip 120a.

The bent portion 132b of the upper attachment film 130b may be in contact with the lower surface of the attachment portion 131b, the rear surface BS1 of the intermediate semiconductor chip 120a, and the lower surface of the intermediate attachment film 130a. The bent portion 132b of the upper attachment film 130b may conformally extend along the lower surface of the attachment portion 131b, the rear surface BS1 of the intermediate semiconductor chip 120a, and the lower surface of the intermediate attachment film 130a. According to some implementations, the bent portion 132b of the upper attachment film 130b may be in contact with the upper surface 110s of the substrate 110. In some implementations, the bent portion 132b of the upper attachment film 130b may be connected to a dummy pad, a dummy pattern, a dummy bump, for heat dissipation, and the like, within the substrate 110.

The mold layer 140 may cover the chip stack CS1 and bonding wires 125 on the substrate 110. The mold layer 140 may include a thermosetting resin, such as an epoxy resin, a thermoplastic resin such as a polyimide, or a resin impregnated with an inorganic filler in these resins, for example, prepreg, Ajinomoto Build-up Film (ABF), Flame Resistant 4 (FR-4), Bismaleimide Triazine (BT), or Epoxy Molding Compound (EMC).

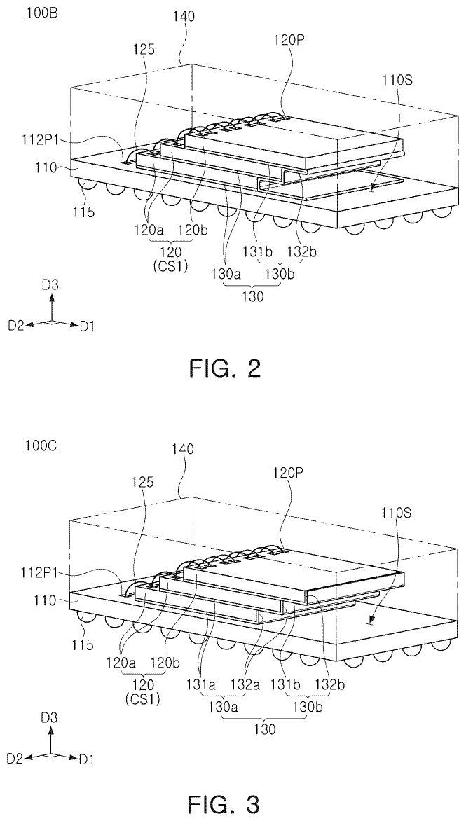

FIG. 2 is a perspective view of an example of a semiconductor package according to some implementations. In FIG. 2, a semiconductor package 100B may have features the same as or similar to those described with reference to FIGS. 1A and 1B, except that an upper attachment film 130b extends along an upper surface 1105 of the substrate 110. In some implementations, a first length of the upper attachment film 130b in a first direction D1 may be greater than a first width of the upper semiconductor chip 120b in the first direction D1. The upper attachment film 130b may include a bent portion 132b extending along a rear surface BS1 of an intermediate semiconductor chip 120a facing the first direction D1 to an upper surface 1105 of the substrate 110. The bent portion 132b of the upper attachment film 130b may conformally extend along a lower surface of the attachment portion 131b, the rear surface BS1 of the intermediate semiconductor chip 120a, a lower surface of the intermediate attachment film 130a, and the upper surface 1105 of the substrate 110.

FIG. 3 is a perspective view of an example of a semiconductor package according to some implementations. In FIG. 3, a semiconductor package 100C may have the same or similar features as described with reference to FIGS. 1A to 2, except that each of the plurality of attachment films 130 covers one side surface of a corresponding semiconductor chip 120. The plurality of attachment films 130 may include an upper attachment film 130b and an intermediate attachment film 130a. The upper attachment film 130b may include an attachment portion 131b contacting a lower surface of the upper semiconductor chip 120b, and a bent portion 132b contacting a rear surface of the upper semiconductor chip 120b. The intermediate attachment film 130a may include an attachment portion 131a contacting a lower surface of the intermediate semiconductor chip 120a, and a bent portion 132a contacting a rear surface of the intermediate semiconductor chip 120a. The upper attachment film 130b and the intermediate attachment film 130a may be in contact with each other to form a heat dissipation path which is connected along side surfaces of the plurality of semiconductor chips 120.

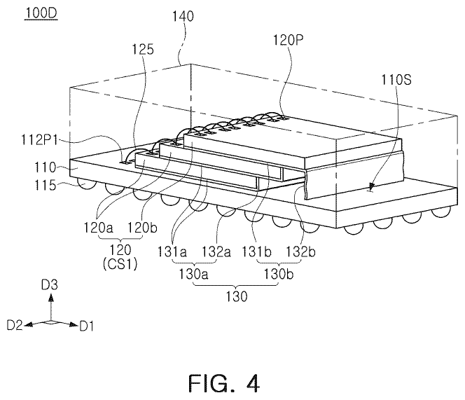

FIG. 4 is a perspective view of an example of a semiconductor package according to some implementations. In FIG. 4, a semiconductor package 100D may have the same or similar features as described with reference to FIGS. 1A to 3, except that a bent portion 132b of the upper attachment film 130b is spaced apart from the intermediate semiconductor chip 120a. The upper attachment film 130b may include an attachment portion 131b contacting a lower surface of the upper semiconductor chip 120b, and a bent portion 132b extending from one end of the attachment portion 131b to the upper surface 1105 of the substrate 110. An intermediate attachment film 130a may include an attachment portion 131a that contacts contacting a lower surface of the intermediate semiconductor chip 120a, and a bent portion 132a contacting a rear surface of the intermediate semiconductor chip 120a. The bent portion 132a of the intermediate attachment film 130a may be in contact with the attachment portion 131b of the upper attachment film 130b.

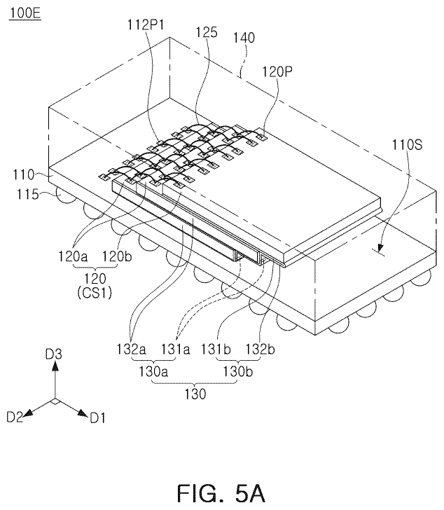

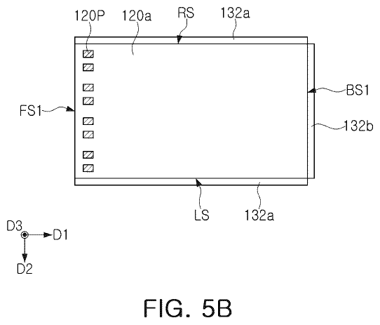

FIG. 5A is a perspective view of an example of a semiconductor package according to some implementations, and FIG. 5B is a plan view of the intermediate semiconductor chip illustrated in 5A according to some implementations. In FIGS. 5A and 5B, a semiconductor package 100E may have the same or similar features as described with reference to FIGS. 1A to 3, except that the semiconductor package 100E includes an attachment film (e.g., 130a) covering two or more side surfaces of a corresponding semiconductor chip (e.g., 120a). In some implementations, the upper attachment film 130b may include an attachment portion 131b contacting a lower surface of the upper semiconductor chip 120b, and a bent portion 132 contacting a rear surface BS1 of the intermediate semiconductor chip 120a. The intermediate attachment film 130a may include an attachment portion 131a contacting a lower surface of the intermediate semiconductor chip 120a, and a bent portion 132a contacting at least one of the front surface FS1, the left surface LS, and the right surface RS of the intermediate semiconductor chip 120a. Here, the front surface FS1 and the rear surface BS1 may be defined as side surfaces that are disposed opposite to each other in the first direction D1, and the left surface LS and the right surface RS may be defined as side surfaces that are disposed opposite to each other in the second direction D2.

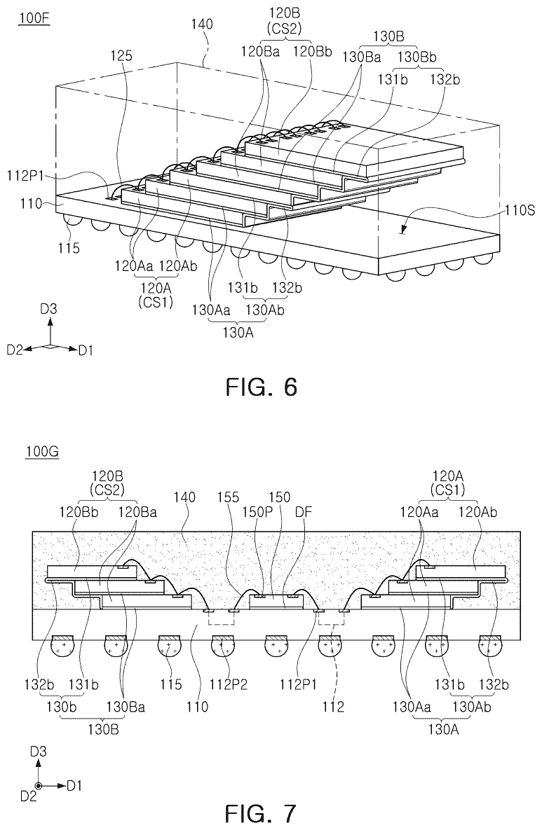

FIG. 6 is a perspective view of an example of a semiconductor package according to some implementations. In FIG. 6, a semiconductor package 100F may have the same or similar features as described with reference to FIGS. 1A to 5B, except that the semiconductor package 100F includes a plurality of chip stacks CS1 and CS2. The semiconductor package 100F may include a first chip stack CS1 and a second chip stack CS2 disposed on a substrate 110. The first chip stack CS1 and the second chip stack CS2 may be electrically connected to the substrate 110 via bonding wires 125. The first chip stack CS1 and the second chip stack CS2 may include memory chips of the same type, but the present disclosure is not limited thereto.

The first chip stack CS1 may include a plurality of first semiconductor chips 120A. The plurality of first semiconductor chips 120A may include a first upper semiconductor chip 120Ab and a first intermediate semiconductor chip 120Aa between the substrate 110 and the first upper semiconductor chip 120Ab. The plurality of first attachment films 130A may include a first upper attachment film 130Ab and a first intermediate film 130Aa. The first upper attachment film 130Ab may include an attachment portion 131b contacting a lower surface of the first upper semiconductor chip 120Ab and a bent portion 132b contacting a rear surface of the first intermediate semiconductor chip 120Aa.

The second chip stack CS2 may be disposed on the first chip stack CS1. The second chip stack CS2 may include a plurality of second semiconductor chips 120B. The plurality of second semiconductor chips 120B may include a second upper semiconductor chip 120Bb and a second intermediate semiconductor chip 120Ba between the first upper semiconductor chip 120Ab and the second upper semiconductor chip 120Bb. The plurality of second attachment films 130B may include a second upper attachment film 130Bb and a second intermediate attachment film 130Ba. A length of the second upper attachment film 130Bb in a first direction D1 may be greater than a width of the second upper semiconductor chip 120Bb in the first direction D1. The second upper attachment film 130Bb may include an attachment portion 131b contacting a lower surface of the second upper semiconductor chip 120Bb and a bent portion 132b contacting a rear surface of the second intermediate semiconductor chip 120Ba. According to some implementations, the bent portion 132b of the second upper attachment film 130Bb may extend to a rear surface of the first upper semiconductor chip 120Ab.

FIG. 7 is a cross-sectional side view of an example of a semiconductor package according to some implementations. In FIG. 7, a semiconductor package 100G may have the same or similar features as described with reference to FIGS. 1A to 6, except that the semiconductor package 100G includes a plurality of chip stacks CS1 and CS2 spaced apart in a horizontal direction. The plurality of chip stacks CS1 and CS2 may include, for example, a first chip stack CS1 and a second chip stack CS2. In the drawing, the first chip stack CS1 and the second chip stack CS2 are disposed in a ‘V’ shape, to be spaced apart from each other in the first direction D1 on the substrate 110, but may be disposed in an ‘A’ shape according to some implementations.

According to some implementations, the semiconductor package 100G may further include an additional semiconductor chip 150 mounted on the substrate 110. The additional semiconductor chip 150 may be connected to the first chip stack CS1 and the second chip stack CS2. The additional semiconductor chip 150 may be mounted on the substrate 110 by a wire bonding method. For example, a connection terminal 150P of the additional semiconductor chip 150 may be electrically connected to the wiring 112 of the substrate 110 through a bonding wire 155. An adhesive layer DF may be disposed between the additional semiconductor chip 150 and the substrate 110. In some implementations, the additional semiconductor chip 150 may be mounted using a flip-chip bonding method. According to some implementations, the additional semiconductor chip 150 may include a controller chip for determining a data processing order of the first chip stack CS1 and the second chip stack CS2, and preventing errors and bad sectors, and/or a Frequency Boosting Interface (FBI) for controlling loading of the first chip stack CS1 and the second chip stack CS2.

FIGS. 8A to 8C are drawings for illustrating an example of a manufacturing process of an attachment film 130 that includes a bent portion 132 according to some implementations. FIGS. 8B to 8C illustrate an example of a cut attachment film 130 according to some implementations.

In FIG. 8A, a plurality of semiconductor chips 120 may be attached on a pre-attachment film 130′. The pre-attachment film 130′ may include die attachment regions DR separated by scribe lanes SL. The pre-attachment film 130′ may be a film sheet having a circular or rectangular shape. The die attach regions DR may have a planar area greater than a planar area of the semiconductor chip 120. The die attach regions DR may have a width greater than the length of the semiconductor chip 120 in at least one direction. In FIG. 8A, the die attach regions DR is illustrated to be elongated in a direction of the rear surface of a corresponding semiconductor chip 120, but the present disclosure is not limited thereto. By cutting the pre-attachment film 130′ along the scribe lane SL using a sawing tool (e.g., blade, laser, or the like), the attachment film 130 in contact with the lower surface of the corresponding semiconductor chip 120 may be separated. The semiconductor chip 120 may be disposed on a boundary between the die attach region DR and the scribe lane SL in at least one direction, except for the direction in which the die attach region DR extends elongatedly, or may be disposed on the scribe lane SL outside the die attach region DR. A portion of an edge of the semiconductor chip 120 disposed on the scribe lane SL may be removed together with the scribe lane SL in the sawing process.

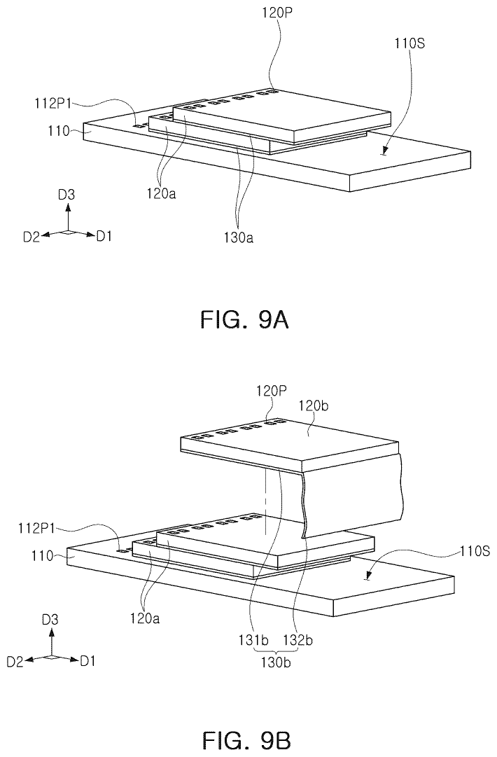

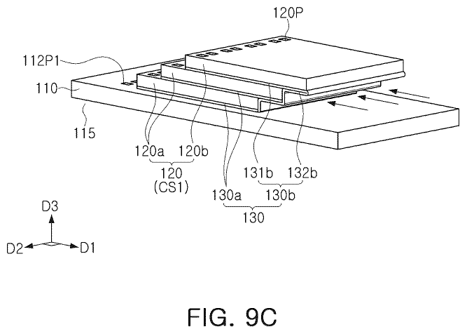

In FIG. 8B, in some implementations, the semiconductor chip 120 may have a first width W1 in a first direction D1 and a second width W2 in a second direction D2, and the attachment film 130 may have a first length L1 in the first direction D1 and a second length L2 in the second direction D2. The first length L1 of the attachment film 130 may be greater than the first width W1 of the semiconductor chip 120. The second length L2 of the attachment film 130 may be equal to the second width W2 of the semiconductor chip 120. Here, ‘same’ includes a tolerance, and means that a side surface of the semiconductor chip 120 facing the second direction D2 and a side surface of the attachment film 130 are cut together. The attachment film 130 may include a bent portion 132 protruding from a rear surface of the semiconductor chip 120. Since the attachment film 130 is a flexible film, the bent portion 132 attached to the semiconductor chip 120 may be bent downwardly (see. FIG. 9B). It can be understood that the attachment film 130 may be applied to the upper attachment film 130b described above.

In FIG. 8C, a first length L1 of the attachment film 130 may be equal to a first width W1 of the semiconductor chip 120. A second length L2 of the attachment film 130 may be greater than a second width W2 of the semiconductor chip 120. Here, ‘same’ includes a tolerance, and means that a side surface of the semiconductor chip 120 facing the first direction D1 and a side surface of the attachment film 130 are cut together. The attachment film 130 may include a bent portion 132 protruding further than the left surface and right surface of the semiconductor chip 120. Since the attachment film 130 is a flexible film, the bent portion 132 that is not attached to the semiconductor chip 120 may be bent downwardly. It can be understood that the attachment film 130 may be applied to the intermediate attachment film 130a illustrated in FIGS. 5A and 5B.

FIGS. 9A to 9C are drawings for illustrating an example of a manufacturing process of the semiconductor package 100A of FIG. 1A according to some implementations.

In FIG. 9A, intermediate semiconductor chips 120a may be disposed on a substrate 110. The substrate 110 may be one of a plurality of unit substrates included in a strip substrate. Intermediate semiconductor chips 120a may be stacked in a vertical direction D3 on the substrate 110. Intermediate attachment films 130a may be disposed on a lower surface of each of the intermediate semiconductor chips 120a. The intermediate semiconductor chips 120a may be disposed so that each of respective connection pads 120P is adjacent to bonding pads 112P1 of the substrate 110. The intermediate semiconductor chips 120a may be offset in a first direction D1 so that the connection pads 120P are exposed in a vertical direction (D3 direction).

In FIG. 9B, upper semiconductor chip 120b may be disposed. The upper semiconductor chip 120b may be stacked to be offset from the intermediate semiconductor chips 120a in the first direction D1. An upper attachment film 130b may be disposed below the upper semiconductor chip 120b. The upper attachment film 130b may include an attachment portion 131b contacting a lower surface of the upper semiconductor chip 120b and a bent portion 132b extending from one end of the attachment portion 131b. The bent portion 132b of the upper attachment film 130b may not be attached to the upper semiconductor chip 120b, and may be bent downwardly.

In FIG. 9C, an upper attachment film 130b may be attached to rear surfaces of intermediate semiconductor chips 120a. The upper attachment film 130b may be attached to a lower surface of the attachment portion 131b of the upper attachment film 130b, rear surfaces of the intermediate semiconductor chips 120a, and a lower surface of the intermediate attachment film 130a, by pressing the bent portion 132b of the upper attachment film 130b using a pressing tool of an appropriate shape (e.g., a jig, or the like). One surface of the pressing tool may be coated with an anti-adhesive material to prevent the bent portion 132b from being adhered. Accordingly, a subsequent process (wire bonding process, molding process, solder ball attachment process, sawing process, or the like) may be performed to manufacture a semiconductor package.

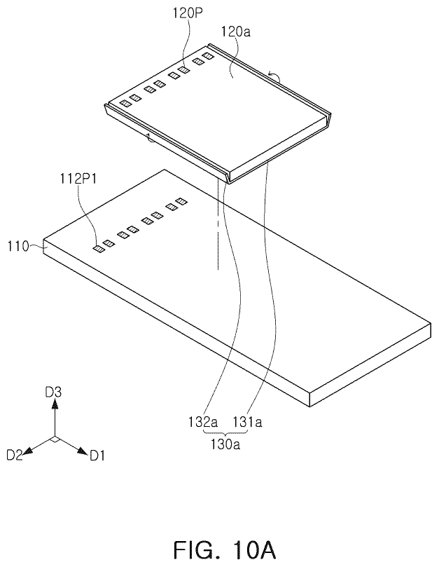

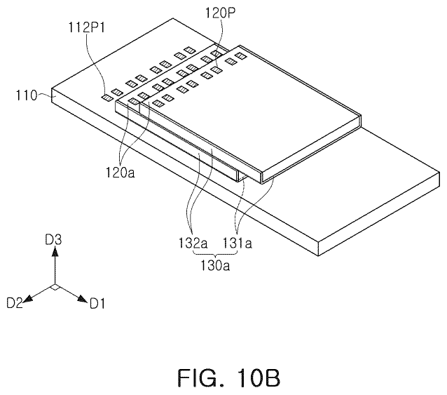

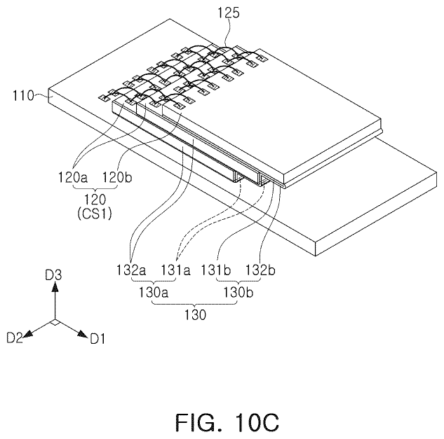

FIGS. 10A to 10C are drawings for illustrating an example of a manufacturing process of the semiconductor package 100E of FIG. 5A according to some implementations. In FIG. 10A, an intermediate semiconductor chip 120a may be disposed on the substrate 110. An intermediate attachment film 130a may be disposed below the intermediate semiconductor chip 120a. The intermediate attachment film 130a may include an attachment portion 131a contacting a lower surface of the intermediate semiconductor chip 120a and a bent portion 132a extending from both ends of the attachment portion 131a. The bent portion 132a of the intermediate attachment film 130a may be bent downwardly without being attached to the intermediate semiconductor chip 120a. Using a press tool of an appropriate shape (e.g., a jig, or the like), the bent portion 132a of the intermediate attachment film 130a may be attached to the left and right surfaces of the intermediate semiconductor chips 120a.

In FIG. 10B, intermediate semiconductor chips 120a may be stacked on the substrate 110. The intermediate semiconductor chips 120a may be offset in a first direction D1 so that the connection pads 120P are exposed in a vertical direction (D3 direction). Intermediate attachment films 130a may be disposed on a lower surface of each of the intermediate semiconductor chips 120a. The intermediate attachment films 130a may include a bent portion 132a contacting the left and right surfaces of the corresponding intermediate semiconductor chip 120a.

In FIG. 10C, an upper semiconductor chip 120b may be disposed. The upper semiconductor chip 120b may be stacked to be offset from the intermediate semiconductor chips 120a in a first direction D1. The upper attachment film 130b may include an attachment portion 131b contacting a lower surface of the upper semiconductor chip 120b and a bent portion 132b extending from one end of the attachment portion 131b. The bent portion 132b of the upper attachment film 130b may be attached to the rear surfaces of the intermediate semiconductor chips 120a (see FIGS. 9B and 9C). Accordingly, after the bonding wires 125 are formed, a subsequent process (molding process, solder ball attachment process, sawing process, or the like) may be performed to manufacture a semiconductor package.

As set forth above, according to some implementations, by introducing an attachment film covering a side surface of a semiconductor chip, a semiconductor package having improved heat dissipation characteristics and reliability may be provided.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a substrate including a wiring;
a chip stack including a plurality of semiconductor chips on the substrate, wherein each of the plurality of semiconductor chips has:
an upper surface and a lower surface opposite to each other,
a front surface and a rear surface opposite to each other,
a left surface and a right surface opposite to each other, and
connection pads on the upper surface adjacent to the front surface;
bonding wires electrically connecting the connection pads to the wiring of the substrate;
a plurality of attachment films on the lower surface of the plurality of semiconductor chips, respectively;
a mold layer covering the chip stack and the bonding wires; and
connection bumps below the substrate, the connection bumps being electrically connected to the wiring,
wherein at least one of the plurality of attachment films covers the rear surface of at least one semiconductor chip among the plurality of semiconductor chips.

2. The semiconductor package of claim 1, wherein the plurality of semiconductor chips are offset from each other to at least partially expose the connection pads in a vertical direction.

3. The semiconductor package of claim 2, wherein the at least one of the plurality of attachment films includes:
an attachment portion contacting the lower surface of a corresponding semiconductor chip among the plurality of semiconductor chips, and
a bent portion contacting the rear surface of the at least one semiconductor chip.

4. The semiconductor package of claim 1,
wherein the plurality of semiconductor chips include an upper semiconductor chip and at least one intermediate semiconductor chip between the substrate and the upper semiconductor chip, and
wherein the plurality of attachment films include:
an upper attachment film on the lower surface of the upper semiconductor chip, and
at least one intermediate attachment film on the lower surface of each of the at least one intermediate semiconductor chip.

5. The semiconductor package of claim 4, wherein the upper attachment film includes:
an attachment portion contacting the lower surface of the upper semiconductor chip, and
a bent portion contacting a lower surface of the attachment portion, the rear surface of the at least one intermediate semiconductor chip, and a lower surface of the at least one intermediate attachment film.

6. The semiconductor package of claim 5, wherein the bent portion of the upper attachment film contacts an upper surface of the substrate.

7. The semiconductor package of claim 5, wherein the at least one intermediate attachment film includes:
an attachment portion contacting the lower surface of the at least one intermediate semiconductor chip, and
a bent portion contacting at least one of the front surface, the left surface, or the right surface of the at least one intermediate semiconductor chip.

8. The semiconductor package of claim 4,
wherein the upper attachment film includes (i) an attachment portion contacting the lower surface of the upper semiconductor chip and (ii) a bent portion contacting the rear surface of the upper semiconductor chip, and
wherein the at least one intermediate attachment film includes (i) an attachment portion contacting the lower surface of the at least one intermediate semiconductor chip and (ii) a bent portion contacting the rear surface of the at least one intermediate semiconductor chip.

9. The semiconductor package of claim 4,
wherein the upper attachment film includes (i) an attachment portion contacting the lower surface of the upper semiconductor chip and (ii) a bent portion extending from a first end of the attachment portion to an upper surface of the substrate, and
wherein the at least one intermediate attachment film includes (i) an attachment portion contacting the lower surface of the at least one intermediate semiconductor chip and (ii) a bent portion contacting the rear surface of the at least one intermediate semiconductor chip.

10. The semiconductor package of claim 9, wherein the bent portion of the at least one intermediate attachment film is in contact with the attachment portion of the upper attachment film.

11. The semiconductor package of claim 1, wherein the plurality of attachment films include thermally conductive fillers.

12. The semiconductor package of claim 11, wherein the thermally conductive fillers include at least one of alumina (Al₂O₃), aluminum nitride (AlN), boron nitride (BN), magnesium oxide (MgO), zinc oxide (ZnO), or silica (SiO₂).

13. The semiconductor package of claim 1, comprising:
an additional semiconductor chip on a side of the chip stack, the additional semiconductor chip being electrically connected to the wiring.

14. A semiconductor package, comprising:
a substrate;
at least one chip stack including a plurality of semiconductor chips on the substrate, wherein each of the plurality of semiconductor chips includes:
a front surface and a rear surface opposite to each other in a first direction, and
a left surface and a right surface opposite to each other in a second direction intersecting the first direction;
bonding wires electrically connecting the plurality of semiconductor chips to the substrate; and
a plurality of attachment films below a corresponding semiconductor chip among the plurality of semiconductor chips, respectively
wherein at least one of the plurality of attachment films has a first length in the first direction and a second length in the second direction,
wherein a semiconductor chip corresponding to the at least one of the plurality of attachment films has a first width in the first direction and a second width in the second direction, and
wherein at least one of the first length or the second length is greater than at least one of the first width or the second width.

15. The semiconductor package of claim 14,
wherein the plurality of semiconductor chips include an upper semiconductor chip and at least one intermediate semiconductor chip disposed between the substrate and the upper semiconductor chip,
wherein the plurality of attachment films include an upper attachment film on a lower surface of the upper semiconductor chip and at least one intermediate attachment film on a lower surface of the at least one intermediate semiconductor chip, and
wherein the first length of the upper attachment film is greater than the first width of the upper semiconductor chip.

16. The semiconductor package of claim 15, wherein the second length of the upper attachment film is a same as the second width of the upper semiconductor chip.

17. The semiconductor package of claim 14, wherein the at least one of the plurality of attachment films is in contact with an upper surface of the substrate.

18. A semiconductor package, comprising:
a substrate;
a first chip stack on the substrate, the first chip stack including a first upper semiconductor chip and a first intermediate semiconductor chip between the substrate and the first upper semiconductor chip;
bonding wires electrically connecting the first upper semiconductor chip and the first intermediate semiconductor chip to the substrate;
a first upper attachment film below the first upper semiconductor chip; and
a first intermediate attachment film below the first intermediate semiconductor chip,
wherein a length of the first upper attachment film in a first direction is greater than a width of the first upper semiconductor chip in the first direction.

19. The semiconductor package of claim 18,
wherein the first upper attachment film contacts a rear surface of the first upper semiconductor chip and
wherein the first intermediate semiconductor chip faces the first direction.

20. The semiconductor package of claim 18, comprising:
a second chip stack on the first chip stack, the second chip stack including a second upper semiconductor chip and a second intermediate semiconductor chip between the first chip stack and the second upper semiconductor chip;
a second upper attachment film below the second upper semiconductor chip; and
a second intermediate attachment film below the second intermediate semiconductor chip,
wherein a length of the second upper attachment film in the first direction is greater than a width of the second upper semiconductor chip in the first direction.
